(19) United States
(12) Patent Application Publication
(10) Pub. No.: US 2026/0110503 A1
(43) Pub. Date: Apr. 23, 2026

(54) HEAT DISSIPATION STRUCTURE

(71) Applicants: TZU-CHIA TAN, TAOYUAN CITY (TW); YAO-CHUN WANG, TAOYUAN CITY (TW); EVERBRITE TECHNOLOGY CO., LTD., TAOYUAN CITY (TW)

(72) Inventors: TZU-CHIA TAN, TAOYUAN CITY (TW); YAO-CHUN WANG, TAOYUAN CITY (TW); CHANG-JU LU, TAOYUAN CITY (TW); WEN-YUAN CHOU, TAOYUAN CITY (TW); WEN-HUNG LIN, TAOYUAN CITY (TW)

(21) Appl. No.: 18/982,474

(22) Filed: Dec. 16, 2024

(30) Foreign Application Priority Data
Oct. 23, 2024 (TW) 113140337

(51) Int. Cl. F28F 21/08; H05K 7/20

(52) U.S. Cl. CPC F28F 21/089; H05K 7/2029

(57) ABSTRACT

A heat dissipation structure has a casing structure and a chamber defined therein, the chamber contains a two-phase heat dissipation material and at least a partial vacuum environment. The inner surface at least partially includes a water blocking film, which provides excellent waterproof performance, effectively preventing the penetration of moisture or water vapor, enhancing the stability of the vacuum environment within the chamber, and improving the overall performance of the heat dissipation structure, thereby promoting a uniform two-phase flow.

### FIELD OF INVENTION

The present invention relates to a heat dissipation structure, particularly to a two-phase flow heat dissipation structure.

### BACKGROUND OF THE INVENTION

With technological advancements, electronic products have become widely integrated into everyday life. To meet the demand for convenient use, these products are increasingly designed to be multifunctional. However, during operation, electronic products often experience temperature increases due to energy consumption. Existing technologies employ a heat dissipation structure or component to help lower the temperature of these products. Nevertheless, conventional heat dissipation techniques often struggle to effectively regulate the operating temperature of electronic products, resulting in excessive temperatures in high-temperature environments or insufficient warmth in low-temperature settings, thereby impacting the performance and lifespan of the electronic products.

In conventional technology, the heat dissipation structure generally employs a casing structure made from metals with high thermal conductivity and heat diffusion properties. However, this metal casing structure presents challenges such as high costs and complex processing. When using alternative non-metallic materials, the vacuum environment within the heat dissipation structure is susceptible to moisture or vapor infiltration, which reduces heat dissipation efficiency. This impacts the vacuum effect within the heat dissipation mechanism, leading to issues of uneven two-phase flow. Consequently, the heat dissipation performance becomes inconsistent or inefficient.

Therefore, developing a heat dissipation structure that can prevent moisture or vapor infiltration and enhance the uniformity of two-phase flow has become a pressing objective in the relevant field.

### SUMMARY OF THE INVENTION

To develop a heat dissipation structure capable of preventing moisture or vapor infiltration and enhancing the uniformity of two-phase flow, the present invention provides a heat dissipation structure, comprising: a casing structure and a chamber defined in the casing structure, wherein the chamber contains a two-phase heat dissipation material and at least a partial vacuum environment; and a water blocking film formed on at least a portion of an inner surface.

Wherein, the casing structure comprises a plastic substrate or a composite material, wherein the plastic substrate comprises polycarbonate (PC), polyethylene terephthalate (PET), polyimide (PI), polymethyl methacrylate (PMMA), polypropylene (PP), polyethylene (PE), or a combination of one or more of these materials.

Wherein, two water blocking films are respectively placed on two of on at least a portion of the inner surface at opposite positions, the chamber is formed between two water blocking film, and a flow channel is formed within the chamber.

Wherein, the water blocking film is a thin film, and the method of bonding the water blocking film to the casing structure includes coating, electroplating, chemical vapor deposition, physical vapor deposition, melt lamination, or adhesion.

Wherein, the water blocking film is co-extruded, injection molded, or high-pressure molded with the casing structure to form an integral casing structure.

Wherein, a water vapor transmission rate (WVTR) of the casing structure is less than 0.1 g/m² per day.

Wherein, a water vapor transmission rate (WVTR) of the water blocking film is less than 0.1 g/m² per day.

Wherein, the casing structure is formed by two corresponding plates that are assembled together, and the casing structure forms an outer surface of the heat dissipation structure.

Wherein, the casing structure is formed by folding a single plate, and the casing structure forms the outer surface of the heat dissipation structure.

Wherein, the casing structure includes a guiding structure, and the guiding structure is positioned relative to at least one part of the casing structure with respect to the water blocking film, and the guiding structure protrudes from one surface of the water blocking film according to a designed pattern, such that the guiding structure creates a height on the surface of the water blocking film.

Wherein, a water vapor transmission rate (WVTR) of the guiding structure is less than 0.1 g/m² per day.

Wherein, the chamber is provided with a capillary structure, and the capillary structure is formed as a single piece through weaving or sintering, the capillary structure comprising two opposing sides, wherein the opposing sides have different densities.

Wherein, the capillary structure has a low-density region on one side and a high-density region on the other side.

Wherein, the density of one side to the other side of the opposing sides gradually transitions from the high-density region to the low-density region.

Wherein, the collected volatile condensable materials (CVCM) of the capillary structure are less than or equal to 0.1%, and the total mass loss (TML) of the capillary structure is less than 1%.

Wherein, the casing structure and the water blocking film are adhesively bonded through a connecting section with adhesive properties, wherein the connecting section is applied to at least a portion of the surface of the casing structure or to at least a portion of the surface of the water blocking film.

From the above description, it can be seen that the present invention has the following effects:
1. The heat dissipation structure in accordance with the present invention effectively regulates the operating temperature of the electronic device. When the ambient temperature rises, the cooling fluid in a liquid state within the heat dissipation structure absorbs thermal energy and turns into a gaseous state, thus preventing excessive temperature increase in the environment. Conversely, when the ambient temperature decreases, the gaseous cooling fluid releases thermal energy and reverts to the liquid state. This heat dissipation structure helps to maintain a stable environmental temperature, thereby protecting the electronic device from component damage or circuit malfunctions caused by temperature fluctuations.
2. The casing structure in accordance with this invention provides superior signal transmission performance, interference suppression, and excellent insulation properties. Because the casing structure is made of non-conductive material with a low dielectric constant, it minimizes obstruction to electric field variations and effectively isolates current, preventing current loss and electromagnetic interference, thereby enhancing the stability and reliability of signal transmission. Additionally, the low electromagnetic interference characteristic of the casing structure further strengthens its signal protection capability, ensuring effective reduction of external electromagnetic interference on internal signals in various environments, thus safeguarding normal operation of the device.
3. The casing structure in accordance with this invention not only achieves lightweight and transparency effects but also maintains heat dissipation performance, preventing the casing structure from exceeding 45° C., thus enhancing user comfort and reducing potential future customer returns due to overheating. Additionally, with a lower melting point than metal, the casing structure in accordance with this invention has higher moldability, allowing it to accommodate the complex structure of the device, such as a solid-state drive, to improve heat dissipation, thereby enhancing overall performance and the user experience.
4. The water blocking film and the guiding structure in accordance with present invention have excellent waterproof performance, effectively preventing the penetration of moisture or water vapor, enhancing the stability of the vacuum environment within the chamber, and improving the overall performance of the heat dissipation structure in accordance with present invention. The water blocking film in accordance with present invention ensures that the heat dissipation structure can maintain a low boiling point in the vacuum environment, thereby ensuring the stability of the heat dissipation performance.
5. The low-density and high-density areas of the capillary structure in accordance with present invention enhance the efficient distribution and circulation of the cooling fluid. The capillary structure enables balanced flow of both the liquid and gaseous states of the cooling fluid, promoting the return flow of the liquid cooling fluid to the heat source area through capillary action. This effectively maintains the overall heat dissipation efficiency of the heat dissipation structure, improving the stability and long-term reliability of the structure. Furthermore, under high-temperature conditions, the heat dissipation structure in accordance with present invention ensures that its performance is not compromised due to the release of collected volatile condensable materials.
6. The present invention specifically overcomes the issues in prior arts, such as the difficulty in effectively regulating the operating temperature of the electronic product, the influence of moisture or water vapor penetration in the chamber, and the improper circulation of the liquid and gaseous cooling fluids. The present invention provides a high-efficiency, stable, and reliable heat dissipation structure, which further enhances the performance and lifespan of the electronic product.

### BRIEF DESCRIPTION OF THE DRAWINGS

FIG. 1 is an exploded view of a first preferred embodiment in accordance with the present invention;

FIG. 2 is a cross-sectional view of the first preferred embodiment in accordance with the present invention;

FIG. 3 is a cross-sectional view of a second preferred embodiment in accordance with the present invention;

FIG. 4 is a cross-sectional view of a third preferred embodiment in accordance with the present invention;

FIG. 5 is a cross-sectional view of a fourth preferred embodiment in accordance with the present invention; and

FIG. 6 is a schematic diagram of an application of the first preferred embodiment in accordance with the present invention.

### DETAILED DESCRIPTION OF THE PREFERRED EMBODIMENTS

In order to more clearly describe the technical solutions of the embodiments of the present invention, a brief introduction to the drawings used in the description of the embodiments is provided below. Obviously, the drawings in the following description are only some examples or embodiments of the present invention. Those skilled in the art will be able to apply the present invention to other similar scenarios without creative effort based on these drawings. Unless it is apparent from the language context or otherwise indicates, the same reference numbers in the drawings represent the same structures or operations.

As shown in the present invention and claims, unless the context clearly suggests otherwise, the words “a”, “an”, “one”, or “the” do not particularly refer to the singular and may also include the plural. In general, the terms “comprising” and “including” merely indicate the inclusion of the explicitly identified steps and elements, and these steps and elements do not constitute an exclusive listing, and the methods or devices may also include other steps or elements.

The present invention provides a heat dissipation structure 10. The heat dissipation structure 10 includes a casing structure 11, a water blocking film 12, a guiding structure 13, a connecting section 14, and a capillary structure 15.

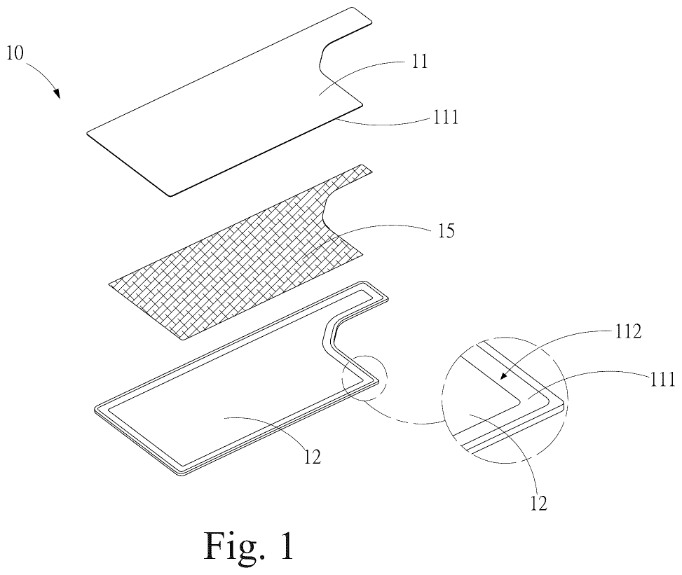

With reference to FIGS. 1 to 6, the heat dissipation structure 10 enables a phase-change fluid to absorb heat provided by the environment when the heat dissipation structure 10 is exposed to a rising ambient temperature, transforming the phase-change fluid into a gaseous state and achieving a cooling effect through phase change. Preferably, when the heat dissipation structure 10 is applied to electronic products such as mobile phones, computers, household appliances, or precision instruments, the heat dissipation structure 10 assists in maintaining the ambient temperature of the electronic product within a stable range. This prevents excessive low or high temperatures that could damage internal components or cause circuit abnormalities, thereby ensuring the operational quality of the electronic product.

With reference to FIGS. 1 to 6, in some preferred embodiments in accordance with the present invention, the casing structure 11 includes one or more plates and an inner surface 111. The shape of the casing structure 11 is not limited. For example, the casing structure 11 may be formed by clamping together two correspondingly shaped plates or by folding a single plate. The casing structure 11 forms an exterior surface of the heat dissipation structure 10.

In some preferred embodiments, the material of the casing structure 11 is not limited. The casing structure 11 may be composed of any plastic substrate or composite material, or the casing structure 11 may partially include plastic substrate. The material of the plastic substrate is also not restricted. In some preferred embodiments, the material of the plastic substrate includes polycarbonate (PC), polyethylene terephthalate (PET), polyimide (PI), polymethylmethacrylate (PMMA), polypropylene (PP), polyethylene (PE), or a combination of one or more of these materials. The casing structure 11 may be translucent, colored, or include printed coatings. In another embodiment, the casing structure 11 incorporates materials of other compositions, such as ceramic powder or carbon fiber laminates, and is formed into a composite material plastic substrate through co-extrusion blow molding, injection molding, or high-pressure molding.

At least a portion of the inner surface 111 defines a chamber 112. Preferably, a flow channel can be formed within the chamber 112. The chamber 112 contains a cooling fluid. Furthermore, the chamber 112 undergoes a vacuuming process either before or after filling with the cooling fluid to create a vacuum or a negative pressure environment. As the ambient temperature increases, the proportion of the cooling fluid in the gaseous state increases.

As shown in FIG. 1, the casing structure 11 of this embodiment includes two plastic substrates with corresponding shapes. After the casing structure 11 is oppositely clamped together, the inner surface 111 is formed between the two plastic substrates of the casing structure 11, and the chamber 112 is defined within at least a portion of the inner surface 111.

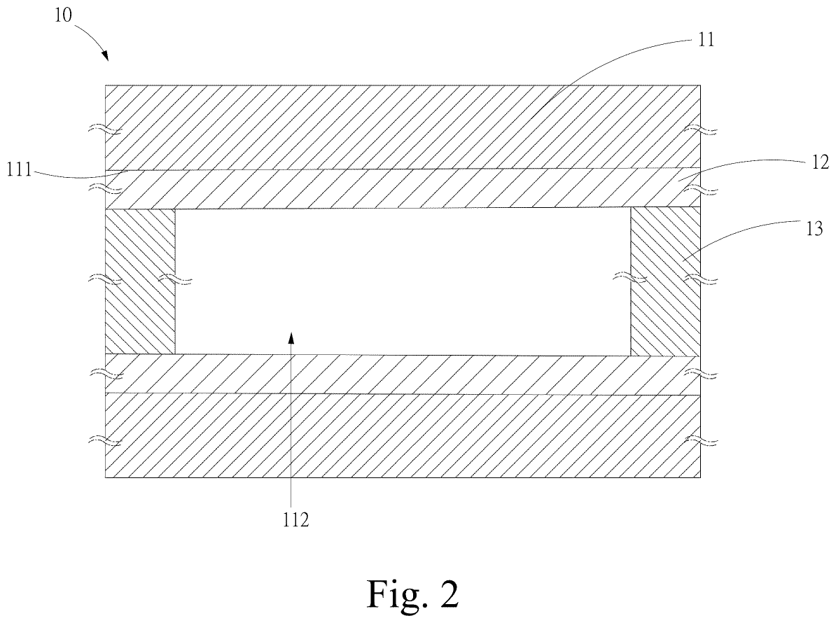

As shown in FIGS. 2 to 6, the water blocking film 12 is positioned within the casing structure 11. The water blocking film 12 is a thin membrane, with at least a portion of the water blocking film 12 abutting against the inner surface 111. The chamber 112 is thus formed within the water blocking film 12.

The water blocking film 12 can be a thin membrane, and the water blocking film 12 can be bonded to the casing structure 11 by coating, electroplating, chemical vapor deposition, physical vapor deposition, melt lamination, or adhesion. Furthermore, the water blocking film 12 may also be formed by applying a liquid form of the water blocking film 12 onto the casing structure 11 and then drying it to form the thin membrane. Additionally, the water blocking film 12 can be integrally formed with the casing structure 11 through co-extrusion blow molding, injection molding, or high-pressure molding.

The water blocking film 12 possesses excellent waterproof properties, effectively preventing moisture or water vapor from permeating into the chamber 112, thereby further enhancing the vacuum level within the vacuum environment of the heat dissipation structure 10. Preferably, the material of the water blocking film 12 may be selected from polymers or composite materials with high hydrophobicity and may undergo special treatment to strengthen the waterproof functionality of the water blocking film 12. At the same time, the water blocking film 12 provides benefits of low outgassing and low permeability.

The material of the water blocking film 12 may include coatings or films made of materials such as silicon oxide, silicon nitride, or aluminum oxide. Furthermore, the material of the water blocking film 12 may comprise any metallic coating or metallic film layer.

The water vapor transmission rate (WVTR) of the water blocking film 12 is less than 0.1 g/m² per day. The water vapor transmission rate refers to the amount of water vapor transmitted through the water blocking film 12 per unit area per day. In a preferred embodiment of this invention, the water blocking film 12 possesses exceptionally high water-blocking strength.

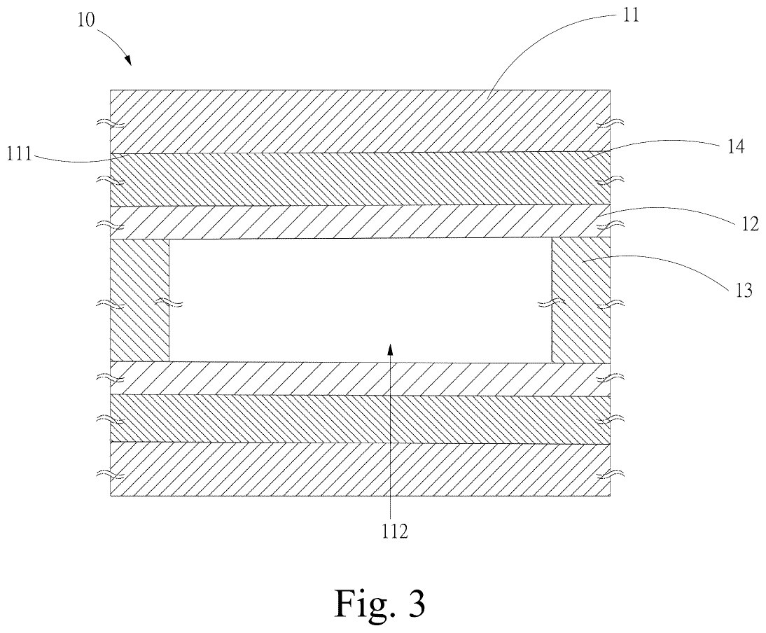

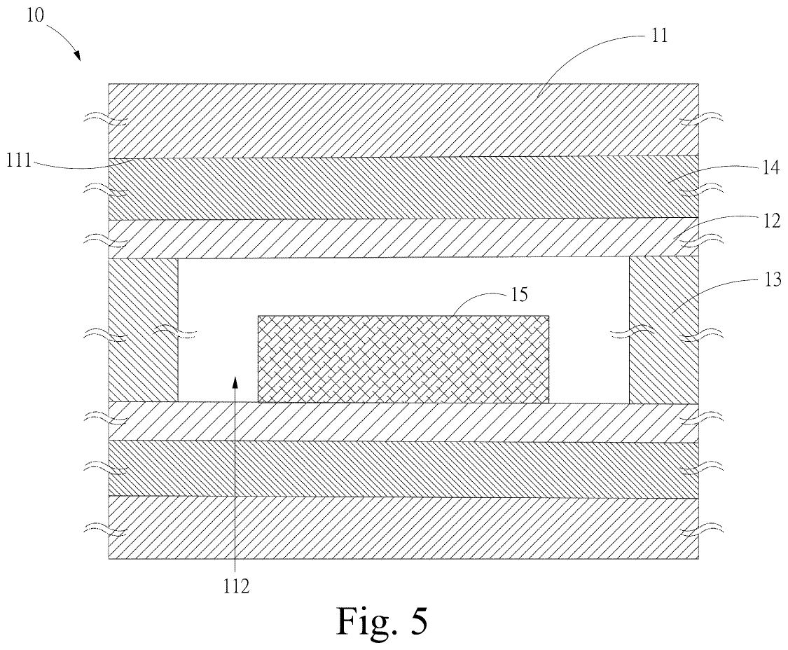

With reference to FIGS. 3 and 5, optionally, the guiding structure 13 may be formed by solidifying an adhesive colloid with viscosity. The guiding structure 13 is used to bond the casing structure 11 or the water blocking film 12. Preferably, the guiding structure 13 is positioned on at least a portion of the water blocking film 12, relative to one of the casing structures 11. Preferably, the guiding structure 13 protrudes on one surface of the water blocking film 12 according to a designed pattern, creating a height difference on one surface of the water blocking film 12.

In this embodiment, the casing structure 11 is joined to the guiding structure 13 on the opposite side of the water blocking film 12. The chamber 112 is in correspondence with the designed pattern, enclosed between the casing structure 11, the water blocking film 12, and the guiding structure 13. The position of the guiding structure 13 may extend to the edge of one surface of the water blocking film 12, and the guiding structure 13 can also serve as an edge-sealing adhesive, achieving a sealing effect upon solidification.

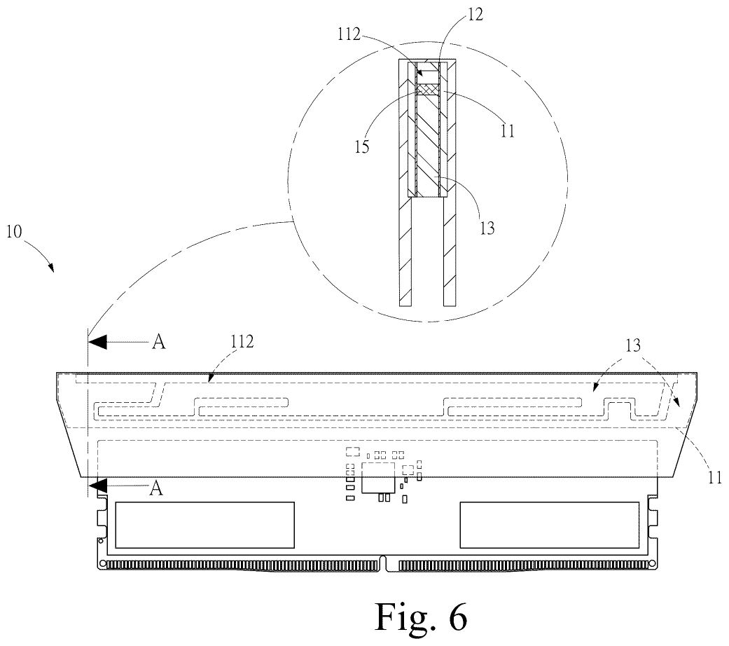

With reference to FIG. 6, the casing structure 11 may be a single molded shell or assembled from two or more corresponding components. In one embodiment, the casing structure 11 includes two casing structures 11 and two water blocking films 12. The two water blocking films 12 are respectively positioned on the inner surfaces 111 of the two casing structures 11, with the guiding structure 13 located between the two water blocking films 12. The chamber 112 is also formed between the two water blocking films 12. The guiding structure 13, once solidified, shapes the chamber 112 according to the designed pattern. The designed pattern can be complex, curved pathways.

The guiding structure 13 possesses low outgassing and low permeability properties. The guiding structure 13 has a water vapor transmission rate (WVTR) of less than 0.1 g/m² per day, and the guiding structure 13 effectively blocks moisture or water vapor from infiltrating the internal components of the heat dissipation structure 10. This further enhances the vacuum level within the heat dissipation structure 10.

Preferably, the chamber 112 is protected by the water blocking film 12 and the guiding structure 13, making the cooling fluid in the chamber 112 maintain a low boiling point in the vacuum environment and generate a two-phase flow.

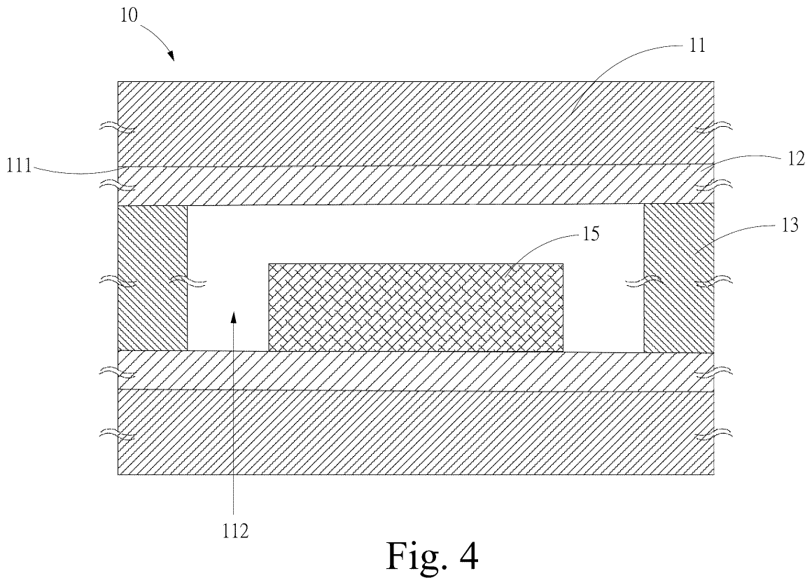

As shown in FIGS. 4 and 5, optionally, the capillary structure 15 is positioned within the chamber 112. The capillary structure 15 can be formed through weaving or sintering to create a single piece. Furthermore, the capillary structure 15 includes two opposite sides, with each side having different densities. One side may have a low-density region, while the other side may have a high-density region. Preferably, the density gradient between the two sides transitions from the high-density region to the low-density region.

Furthermore, the capillary structure 15 distributes the cooling fluid evenly through capillary action. Specifically, at least part of the capillary structure 15 is in contact with the cooling fluid in the liquid state, while another part may be in contact with the cooling fluid in the gaseous state.

The capillary structure 15 is distributed within the chamber 112, or the capillary structure 15 is arranged only in an area corresponding to a heat source provided by the electronic product, facilitating the flow distribution of the cooling fluid in the gaseous state. Furthermore, after the cooling fluid in the liquid state evaporates upon heating, the cooling fluid smoothly returns to the heat source area through capillary action of the capillary structure 15, maintaining the circulation of the cooling fluid in both the liquid and gaseous states.

Preferably, the capillary structure 15 retains the cooling fluid in the liquid state within the high-density region, while allowing the cooling fluid in the gaseous state to flow within the low-density region.

Preferably, the material of the capillary structure 15 includes, but is not limited to, polyamide (Nylon), liquid crystal polymer (LCP), polyethylene terephthalate (PET), polyester fiber, metal, or any combination thereof.

Preferably, in a preferred embodiment of the present invention, collected volatile condensable materials (CVCM) of the capillary structure 15 is less than or equal to 0.1%. The collected volatile condensable materials refer to the amount of condensable substances volatilized by the capillary structure 15 in a vacuum environment. In this preferred embodiment, the collected volatile condensable materials of the capillary structure 15 being less than or equal to 0.1% indicates that the volatilized components of the capillary structure 15 in a vacuum environment are minimal, showing that the capillary structure 15 has good stability and applicability.

Preferably, in the preferred embodiment of the present invention, total mass loss (TML) of the capillary structure 15 is less than 1%. The total mass loss refers to the amount of mass lost by the capillary structure 15 under high-temperature conditions, indicating that the total mass loss is very low. This shows that the capillary structure 15 has good thermal stability and does not experience significant volatilization or decomposition during heating or thermal processing.

From the above description, it can be seen that the present invention achieves the following effects:
1. The heat dissipation structure 10 in accordance with the present invention effectively regulates the operating temperature of the electronic device. When the ambient temperature rises, the cooling fluid in a liquid state within the heat dissipation structure 10 absorbs thermal energy and turns into a gaseous state, thus preventing excessive temperature increase in the environment. Conversely, when the ambient temperature decreases, the gaseous cooling fluid releases thermal energy and reverts to the liquid state. This heat dissipation structure 10 helps to maintain a stable environmental temperature, thereby protecting the electronic device from component damage or circuit malfunctions caused by temperature fluctuations.
2. The casing structure 11 in accordance with this invention provides superior signal transmission performance, interference suppression, and excellent insulation properties. Because the casing structure 11 is made of non-conductive material with a low dielectric constant, it minimizes obstruction to electric field variations and effectively isolates current, preventing current loss and electromagnetic interference, thereby enhancing the stability and reliability of signal transmission. Additionally, the low electromagnetic interference characteristic of the casing structure 11 further strengthens its signal protection capability, ensuring effective reduction of external electromagnetic interference on internal signals in various environments, thus safeguarding normal operation of the device.
3. The casing structure 11 in accordance with this invention not only achieves lightweight and transparency effects but also maintains heat dissipation performance, preventing the casing structure 11 from exceeding 45° C., thus enhancing user comfort and reducing potential future customer returns due to overheating. Additionally, with a lower melting point than metal, the casing structure 11 in accordance with this invention has higher moldability, allowing it to accommodate the complex structure of the device, such as a solid-state drive, to improve heat dissipation, thereby enhancing overall performance and the user experience.
4. The water blocking film 12 and the guiding structure 13 in accordance with present invention have excellent waterproof performance, effectively preventing the penetration of moisture or water vapor, enhancing the stability of the vacuum environment within the chamber 112, and improving the overall performance of the heat dissipation structure 10 in accordance with present invention. The water blocking film 12 in accordance with present invention ensures that the heat dissipation structure 10 can maintain a low boiling point in the vacuum environment, thereby ensuring the stability of the heat dissipation performance.
5. The low-density and high-density areas of the capillary structure 15 in accordance with present invention enhance the efficient distribution and circulation of the cooling fluid. The capillary structure 15 enables balanced flow of both the liquid and gaseous states of the cooling fluid, promoting the return flow of the liquid cooling fluid to the heat source area through capillary action. This effectively maintains the overall heat dissipation efficiency of the heat dissipation structure 10, improving the stability and long-term reliability of the structure. Furthermore, under high-temperature conditions, the heat dissipation structure 10 in accordance with present invention ensures that its performance is not compromised due to the release of collected volatile condensable materials.
6. The present invention specifically overcomes the issues in prior arts, such as the difficulty in effectively regulating the operating temperature of the electronic product, the influence of moisture or water vapor penetration in the chamber, and the improper circulation of the liquid and gaseous cooling fluids. The present invention provides a high-efficiency, stable, and reliable heat dissipation structure 10, which further enhances the performance and lifespan of the electronic product.

It should be noted that based on the explanations and elaborations in the above specification, those skilled in the art to which this disclosure relates may also make changes and modifications to the above implementation modes. Therefore, this disclosure is not limited to the specific implementation modes disclosed and described above, and some equivalent modifications and changes to this disclosure should also be within the scope of protection of the claims of this disclosure. In addition, although certain terms are used in this disclosure, these terms are used for convenience of description only and do not impose any limitations on the invention.

What is claimed is:

1. A heat dissipation structure, comprising:
A casing structure and a chamber defined in the casing structure, wherein the chamber contains a two-phase heat dissipation material and at least a partial vacuum environment; and
a water blocking film formed on at least a portion of an inner surface of the casing structure.

2. The heat dissipation structure according to claim 1, wherein the casing structure comprises a plastic substrate or a composite material, wherein the plastic substrate comprises polycarbonate (PC), polyethylene terephthalate (PET), polyimide (PI), polymethyl methacrylate (PMMA), polypropylene (PP), polyethylene (PE), or a combination of one or more of these materials.

3. The heat dissipation structure according to claim 2, wherein two water blocking films are respectively placed on two of on at least a portion of the inner surface at opposite positions, the chamber is formed between the two water blocking films, and a flow channel is formed within the chamber.

4. The heat dissipation structure according to claim 3, wherein the two water blocking films are bond to the casing structure by a method includes coating, electroplating, chemical vapor deposition, physical vapor deposition, melt lamination, or adhesion.

5. The heat dissipation structure according to claim 2, wherein the water blocking film is co-extruded, injection molded, or high-pressure molded with the casing structure to form an integral casing structure.

6. The heat dissipation structure according to claim 5, wherein a water vapor transmission rate (WVTR) of the casing structure is less than 0.1 g/m² per day.

7. The heat dissipation structure according to claim 1, wherein a water vapor transmission rate (WVTR) of the water blocking film is less than 0.1 g/m² per day.

8. The heat dissipation structure according to claim 2, wherein a water vapor transmission rate (WVTR) of the water blocking film is less than 0.1 g/m² per day.

9. The heat dissipation structure according to claim 3, wherein a water vapor transmission rate (WVTR) of the water blocking film is less than 0.1 g/m² per day.

10. The heat dissipation structure according to claim 6, wherein a water vapor transmission rate (WVTR) of the water blocking film is less than 0.1 g/m² per day.

11. The heat dissipation structure according to claim 7, wherein the casing structure is formed by two corresponding plates that are assembled together, and the casing structure forms an outer surface of the heat dissipation structure.

12. The heat dissipation structure according to claim 11, wherein the casing structure is formed by folding a single plate, and the casing structure forms the outer surface of the heat dissipation structure.

13. The heat dissipation structure according to claim 10, wherein the casing structure includes a guiding structure, and the guiding structure is positioned relative to at least one part of the casing structure with respect to the water blocking film, and the guiding structure protrudes from one surface of the water blocking film according to a designed pattern, such that the guiding structure creates a height on the surface of the water blocking film.

14. The heat dissipation structure according to claim 13, wherein a water vapor transmission rate (WVTR) of the guiding structure is less than 0.1 g/m² per day.

15. The heat dissipation structure according to claim 14, wherein the chamber is provided with a capillary structure, and the capillary structure is formed as a single piece through weaving or sintering, the capillary structure comprising two opposing sides, wherein the opposing sides have different densities.

16. The heat dissipation structure according to claim 15, wherein the capillary structure has a low-density region on one side and a high-density region on the other side.

17. The heat dissipation structure according to claim 16, wherein the density of one side to the other side of the opposing sides gradually transitions from the high-density region to the low-density region.

18. The heat dissipation structure according to claim 17, wherein the collected volatile condensable materials (CVCM) of the capillary structure are less than or equal to 0.1%, and the total mass loss (TML) of the capillary structure is less than 1%.

19. The heat dissipation structure according to claim 18, wherein the casing structure and the water blocking film are adhesively bonded through a connecting section with adhesive properties, wherein the connecting section is applied to at least a portion of the surface of the casing structure or to at least a portion of the surface of the water blocking film.
